(19) United States
(12) Patent Application Publication
(10) Pub. No.: US 2026/0012133 A1
(43) Pub. Date: Jan. 8, 2026

(54) BIASING CIRCUIT WITH DIGITAL CROSSING CONTROL FOR AC-COUPLED BROADBAND AMPLIFIERS

(71) Applicant: MACOM Technology Solutions Holdings, Inc., Lowell, MA (US)

(72) Inventors: Ariel Leonardo VERA VILLARROEL, Lowell, MA (US); Abdelrahman H. AHMED, Lowell, MA (US)

(21) Appl. No.: 18/762,373

(22) Filed: Jul. 2, 2024

(51) Int. Cl. H03F 1/02; H03F 1/42; H03F 3/45

(52) U.S. Cl. CPC H03F 1/0205; H03F 1/42; H03F 3/45475; H03F 2200/36

(57) ABSTRACT

Circuits, semiconductor devices, and systems are provided. An illustrative circuit includes a first blocking capacitor coupled to an input of an amplifier and a second blocking capacitor coupled to the input of the amplifier, where the first blocking capacitor and the second blocking capacitor provide at least some Direct Current (DC) blocking to the amplifier. The circuit further includes one or more transistors that operate as an amplifying element for the amplifier and a biasing and crossing control circuit to provide bias control and offset compensation for the amplifier, where the biasing and crossing control circuit further provides a crossing control for the amplifier.

### FIELD OF THE DISCLOSURE

The present disclosure is generally directed toward circuits and, in particular, toward amplifier circuits, driver circuits, and biasing circuits.

### BACKGROUND

High speed communication circuits optimize each of their component’s voltages and current consumption for optimal power efficiency. Interconnection of different components often requires an adaptation between voltage domains. One way to implement such adaptation is to utilize Alternating Current (AC) coupling (e.g., Direct Current (DC) blocking) of the information signals. On-chip DC blocking capacitor (C) simplifies the assembly and complexity of the system; however, performance specifications must be maintained.

An important specification is the Low-Cutoff Frequency (LFC) as low frequency content in the signal may cause DC wander and reduced signal to noise ratio (SNR), impacting overall system performance.

To guarantee a low value LFC, the capacitor should form a filter (e.g., a Resistive Capacitive (RC) filter) where the resistive component has a high value to satisfy: LFCtarget=1/(2*pi*R*C).

Single stage amplifiers are used for low power consumption. Single stage amplifiers, however, require specific bias conditions for optimal operation. Because these blocks operate cascaded with other blocks that will be optimized for different biasing conditions, the interface between the blocks typically employ DC blocking capacitors. To define the bias conditions, the input benefits from a circuit that provides proper biasing (e.g., a low value LFC when combined with the blocking cap) and crossing control. These requirements make possible the optimization of the amplifier for signal integrity.

### SUMMARY

Embodiments of the present disclosure contemplate solutions to the above-noted challenges. In particular, an on-chip DC blocked amplifier is provided. In some embodiments, the amplifier includes two or more integrated DC blocking capacitors. Moreover, at its input, the amplifier may utilize a biasing and crossing control circuit that introduces a controlled amount of offset, whose value is set by a crossing control Digital-to-Analog Converter (DAC). The biasing and crossing control circuit output may be provided to a fully-differential Operational Amplifier (OA) that extracts the common-mode voltage and matches the common-mode voltage to the voltage set by a common-mode voltage reference.

According to at least some embodiments of the present disclosure, a biasing and crossing control circuit is contemplated to provide the biasing of the amplifier (e.g., including bias control) as well as crossing control capabilities. The biasing and crossing control circuit may also help define the bias conditions that make possible the optimization of the amplifier.

In some embodiments, a circuit is provided that includes: a first blocking capacitor coupled to an input of an amplifier; a second blocking capacitor coupled to the input of the amplifier; one or more transistors that operate as amplifier components for the amplifier; and a biasing and crossing control circuit to provide bias control and offset compensation for the amplifier, where the biasing and crossing control circuit further provides a crossing control for the amplifier.

In some embodiments, a semiconductor device is provided that includes: an amplifier comprising; a first blocking capacitor; a second blocking capacitor; one or more transistors that operate as amplifier components for the amplifier; and a biasing and crossing control circuit to provide bias control and offset compensation for the amplifier, where the biasing and crossing control circuit further provides a crossing control for the amplifier.

In some embodiments, a system is provided that includes: a first blocking capacitor; a second blocking capacitor; a first transistor that operates as a first amplifier component for the amplifier; a second transistor that operates as a second amplifier component for the amplifier; a biasing and crossing control circuit to provide bias control and offset compensation for the amplifier, where the biasing and crossing control circuit further provides a crossing control for the amplifier.

According to at least some embodiments, the circuit, semiconductor device, and/or system may further include additional circuitry (e.g., one or more circuits) to differentially sense a voltage at the base of the transistors and then use the sensed voltage as an input to the biasing and crossing control circuit.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a block diagram illustrating a communication system according to at least some embodiments of the present disclosure;

FIG. 2 is a block diagram illustrating an amplifier circuit that may be provided as part of transmitter circuit or receiver circuit according to at least some embodiments of the present disclosure;

FIG. 3 illustrates details of a biasing and crossing control circuit according to at least some embodiments of the present disclosure;

FIG. 4 illustrates additional details of a biasing and crossing control circuit according to at least some embodiments of the present disclosure;

FIG. 5A illustrates a transient response of a circuit implementing a minimum value for crossing control according to at least some embodiments of the present disclosure;

FIG. 5B illustrates a transient response of a circuit implementing a nominal value for crossing control according to at least some embodiments of the present disclosure; and

FIG. 5C illustrates a transient response of a circuit implementing a maximum value for crossing control according to at least some embodiments of the present disclosure;

FIG. 6 illustrates a percentage of a single ended signal amplitude when it crosses its complimentary single ended signal according to at least some embodiments of the present disclosure;

FIG. 7 illustrates a frequency response gain versus frequency for a DC coupled and AC coupled circuit according to at least some embodiments of the present disclosure; and

FIG. 8 illustrates a method of configuring and operating an amplifier according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing amplifier circuits, driver circuits, and/or equalizer circuits.

While embodiments of the present disclosure will primarily be described in connection with amplifier circuits used in high-bandwidth applications, it should be appreciated that embodiments of the present disclosure are not so limited. Furthermore, while embodiments of the present disclosure are contemplated for use in connection with high-speed communications over copper or fiber, it should be appreciated that the claims are not limited to high speed electrical and optical or EO communications. Indeed, the biasing and crossing control circuit(s) depicted and described herein may be utilized in any number of applications utilizing an amplifier (e.g., transmitter applications, receiver applications, filtering applications, etc.). Example embodiments of the present disclosure will be described in connection with broadband applications, but it should be appreciated that the circuit(s) depicted and described herein can be utilized in other non-broadband applications.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, or combinations thereof.

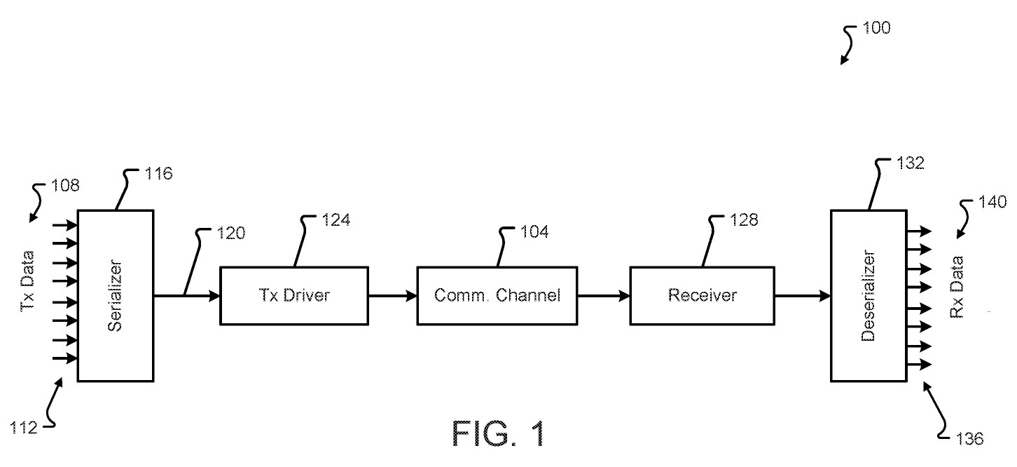

Referring initially to FIG. 1, an illustrative communication system 100 will be described in accordance with at least some embodiments of the present disclosure. The system 100 represents but one possible environment of use of the innovation(s) disclosed herein. As shown, data to be transmitted, referred to as transmit data 108 is provided over two or more parallel paths 112 to a serializer 116. The serializer 116 converts the data received from the two or more parallel paths 112 to a serial stream of data on serial data path 120. The serial stream of data is presented to a transmitter driver 124 which amplifies the signal to a level suitable for transmission over a communication channel 104.

The communication channel 104 may include or correspond to any suitable type of communication channel, such as a channel used for high-speed data transmission. The communication channel 104 may correspond to or include one or more optical fibers. The communication channel 104 may alternatively or additionally correspond to or include one or more electrically-conductive lines such as PCB traces, coaxial cables, connectors, or the like. Thus, the data transmitted by the transmitter driver 124 may include an optical signal and/or electrical signal. In one embodiment, the communication channel 104 is length of optical fiber, which may span in length from few meters to tens of kilometers. However, the method and apparatus disclosed herein may be used for channels of any length or type, such as but not limited to, fiber channels, circuit board traces, coaxial cables, or wired channels, all of which may be any suitable length.

After passing through the communication channel 104, the data is presented to a receiver circuit 128. The receiver circuit 128 may include one or more gain stages. The transmitter driver 124 may include one or more drivers. The transmitter driver 124 and/or receiver circuit 128 may be provided with one or more amplifier circuits comprising one or more biasing and crossing control circuits as depicted and described herein. The transmitter driver 124 and/or receiver circuit 128 may also include one or more equalizer circuits. The equalizer(s) may be configured to reduce the signal attenuating effects of the communication channel 104.

After equalization, the data is provided to a deserializer 132 which converts the serial data stream to a parallel data path on the two or more data paths 136. The data output by the deserializer may be regarded as received data 140 that can be processed by a communication device that includes the receiver circuit 128 and deserializer 132.

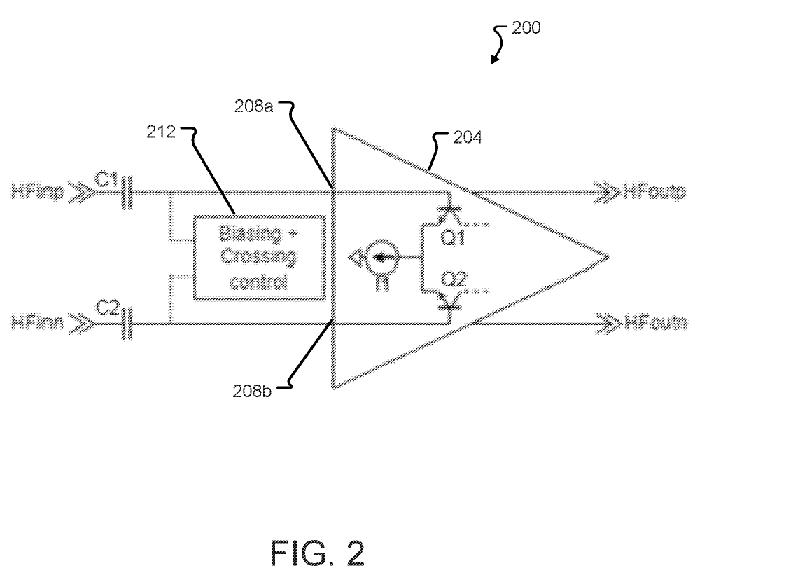

Referring now to FIGS. 2-4, various types of circuit 200 configurations that may be used in connection with a communication system 100 will be described in accordance with at least some embodiments of the present disclosure. As a non-limiting example, the circuit 200 may be provided as part of the transmitter driver 124 that is used to amplify a signal prior to transmission of the signal on the communication channel 104.

FIG. 2 illustrates an example circuit 200 comprising an amplifier 204 having a first input 208a and a second input 208b. The first input 208a may be directly connected to a first capacitor C1. The second input 208b may be directly connected to a second capacitor C2. While not depicted, the amplifier 204 may include a greater or lesser number of inputs. In some embodiments, the first input 208a and second input 208b may be configured to receive high-frequency input signals (e.g., a first high-frequency input HFinp and second high-frequency input HFinn).

The amplifier 204 may be configured to provide one or more high-frequency outputs based on the processing of the high-frequency input(s). The output of the amplifier 204 may include a first high-frequency output HFoutp and a second high-frequency output HFoutn.

In some embodiments, the capacitors C1, C2 may be integrated into the amplifier 204. In some embodiments, the capacitors C1, C2 may be provided external to the amplifier 204. The circuit 200 may be configured to achieve LFC targets on the order of approximately 10kHz, 100kHz, 1MHz, or 10MHz. In such an application, the capacitors C1, C2 may be on the order of one or two pF to tens of pF.

Moreover, at its input, the amplifier 204 may comprise one or more transistors (e.g., a first transistor Q1 and a second transistor Q2) configured as a differential pair. The transistor(s) Q1, Q2 may be configured to operate at relatively high frequencies (e.g., broadband frequencies on the order of 10GHz up to 100GHz). Thus, the inputs provided to the amplifier 204 may have frequency content as large as 10GHz to 100GHz. The transistors Q1, Q2 may also present a high input impedance, which helps obtain a low LFC.

A biasing and crossing control circuit 212 may be provided to correct biasing of the amplifier 204 and to provide crossing control for the amplifier 204. In some embodiments, the biasing and crossing control circuit 212 may be configured to provide biasing control and crossing control to facilitate the optimization of the amplifier 204 for signal integrity. As shown in FIG. 2, the biasing and crossing control circuit 212 may be connected between both capacitors C1, C2 and both transistors Q1, Q2. Moreover, a current source I1 may also be provided between the transistors Q1, Q2. In some embodiments, the biasing and crossing control circuit 212 may provide a high impedance, such the LFC of the amplifier (e.g., where LFC=1/(2*pi*C*Req)) is less than or equal to the target LFC, where C and Req are the total blocking capacitance and total equivalent resistance, respectively. Moreover, the proposed biasing and crossing control circuit 212 may be configured to implement crossing control, which can be programmed digitally

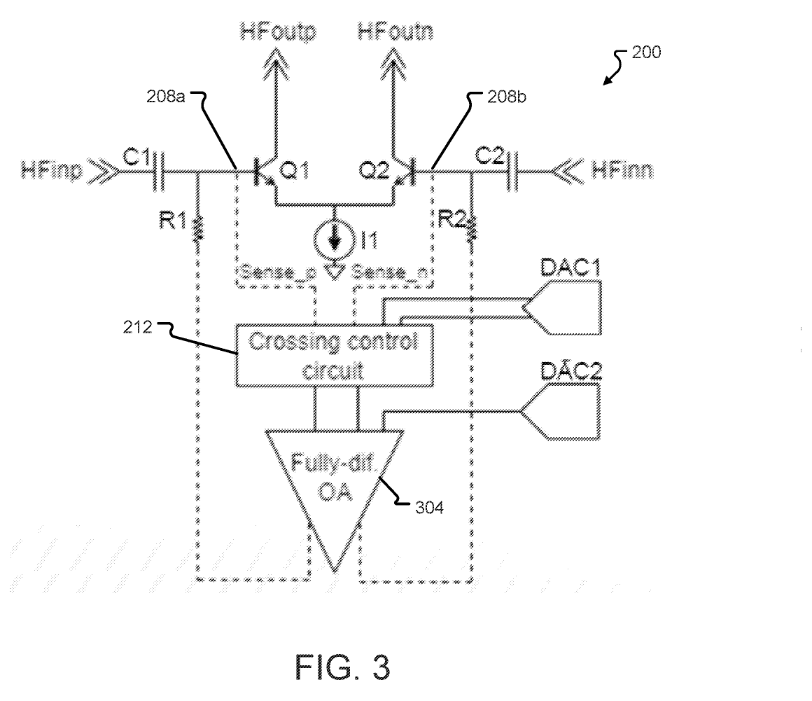

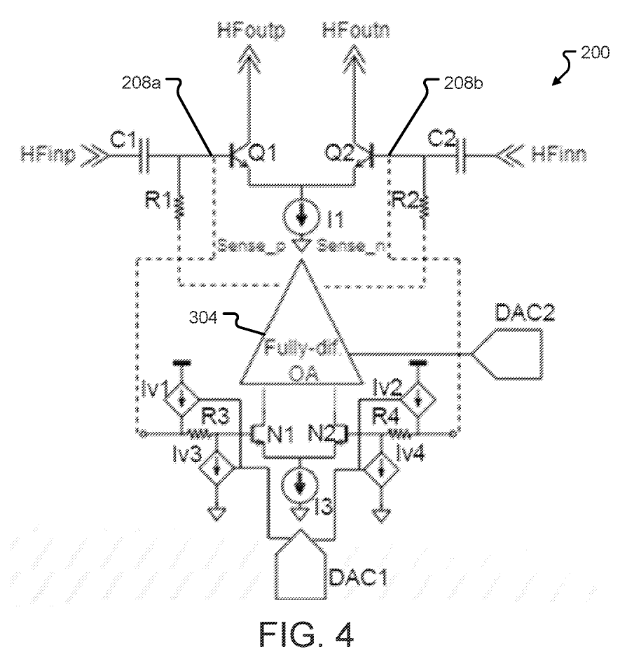

FIGS. 3-4 illustrate additional details of a biasing and crossing control circuit 212 and components thereof in accordance with at least some embodiments of the present disclosure. In the configuration of FIG. 3, the voltage at the base of each transistor Q1, Q2 is sensed differentially. For instance, the voltage at the base of the first transistor Q1 is sensed as a first sensed voltage Sense_p while the voltage at the base of the second transistor Q2 is sensed as a second sensed voltage Sense_n. These sensed voltages are used as an input to the biasing and crossing control circuit 212.

The biasing and crossing control circuit 212 may be configured to introduce a controlled amount of offset, whose value is set by a crossing control DAC, which may also be referred to as DAC1. Based on the sensed voltages Sense_p, Sense_n and the input signal received from the crossing control DAC, the biasing and crossing control circuit 212 may generate an output that is provided to a fully-differential Operational Amplifier (OA) 304. The fully-differential OA 304 extracts the common-mode voltage received from the output of the biasing and crossing control circuit 212 and matches the common-mode voltage to a voltage set by a common-mode voltage reference. The common-mode voltage reference may be received from a second DAC2. In some embodiments, the fully-differential OA 304 matches the common-mode voltage to the common-mode voltage reference by setting the voltage at resistors R1, R2.

The loop provided with the biasing and crossing control circuit 212 along with the fully-differential OA provides an offset at each transistor’s Q1, Q2 base nodes equal in magnitude to the offset set by the crossing control DAC (DAC1). In some embodiments, resistors R1, R2 are chosen to satisfy LFC=1/(2*pi*C*Req) < LFCtarget, where Req is the parallel combination of the transistors input impedance and resistors R1, R2; and C is the equivalent capacitance between the high-frequency inputs. The fixed current source I1 is provided between the transistors Q1, Q2 to help bias each transistor Q1, Q2 substantially simultaneously.

The fully-differential OA 304 may be used to control variable current sources at the bases of the transistors Q1, Q2. In accordance with at least some embodiments, the OA 304 inputs sense the emitter voltages Sense_p, Sense_n of the transistors Q1, Q2, respectively. The OA 304 may also receive a common-mode voltage reference as an input from the crossing control DAC (DAC1). The output of the OA 304 may provide two functions: (1) matching the common-mode voltage value of the two input signals Sense_p, Sense_n to the common-mode voltage reference controlled via the reference DAC (DAC2) and (2) eliminating the differential mode voltage difference (e.g., the offset is cancelled at the inputs of the OA 304).

FIG. 4 illustrates a possible implementation of the biasing and crossing control circuit 212 in accordance with at least some embodiments of the present disclosure. The biasing and crossing control circuit 212, when included in the circuit 200, is shown to include four (4) controlled current sources, which are controlled by complementary outputs of the crossing control DAC (DAC1). The four controlled current sources Iv1, Iv2, Iv3, Iv4 may include variable current sources. Pairs of variable current sources (e.g., a first pair Iv1, Iv3 or second pair Iv2, Iv4 may be coupled with coupling resistors R3, R4, respectively. The sensed voltage has an offset added to it, which depends upon the output of the crossing control DAC (DAC1).

The voltage with the added offset is provided to the input of the fully-differential OA 304, specifically at transistors N1 and N2 (which are part of the OA). The OA output sets the voltage at the bases of the transistors Q1, Q2 via resistors R1, R2. In some embodiments, this voltage is set to be the input voltage plus the added offset. Another fixed current source I3 may also be provided between the transistors N1, N2, which are connected between the crossing control DAC (DAC1) and the fully-differential OA 304.

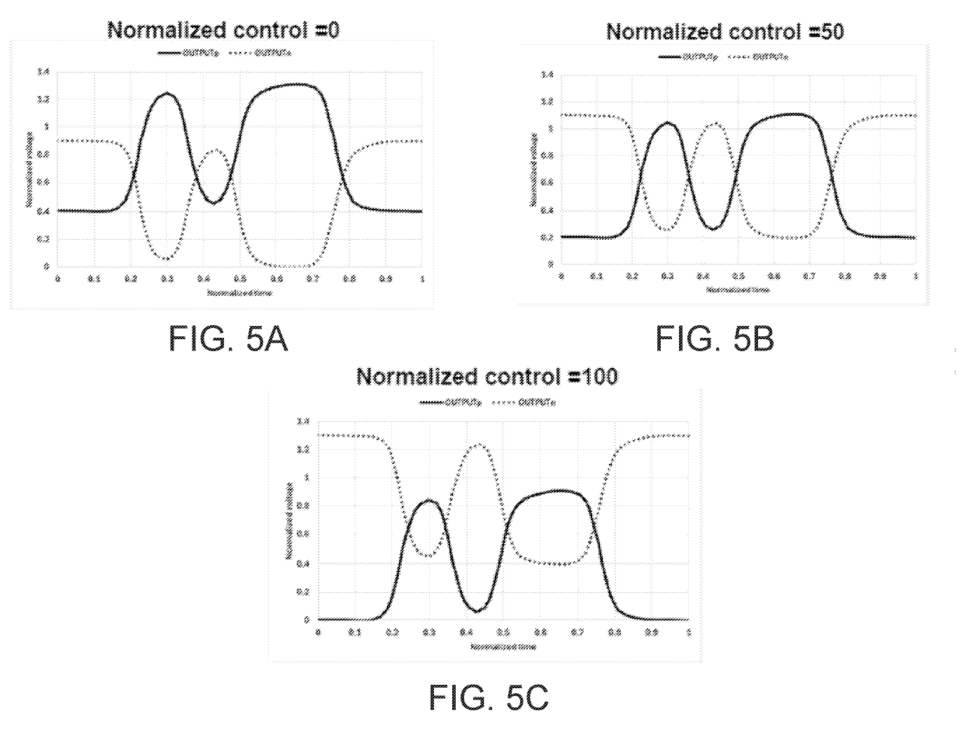

With reference now to FIGS. 5A, 5B, and 5C, different transient responses of the digitally-controlled crossing control functionality will be described in accordance with at least some embodiments. Each diagram illustrates the single ended signals and their change in DC content according to the offset introduced by the crossing control DAC (DAC1).

Specifically, but without limitation, FIG. 5B illustrates a transient response of the circuit 200 where a minimum amount of crossing control functionality is imposed on the circuit 200. In this particular configuration, the offset provided by the crossing control DAC (DAC1) is substantially zero or near zero. FIG. 5A illustrates a second transient response of the circuit 200 where a negative amount of crossing control functionality is imposed on the circuit 200. FIG. 5C illustrates a third transient response of the circuit 200 where a positive amount of crossing control functionality is imposed on the circuit 200. FIGS. 5A and 5C represent the positive and negative extremes in adding an amount of crossing control, with FIG. 5A showing the minimum crossing “value” and FIG. 5C showing the maximum crossing “value.” In some embodiments, the crossing value may be defined by a percentage of a single ended signal amplitude when it crosses its complimentary single ended signal.

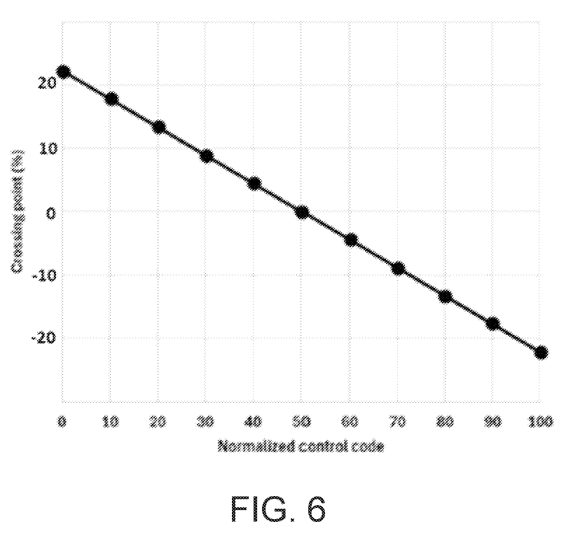

FIG. 6 illustrates the percentage of the single ended amplitude when it crosses the other single ended signal. In some embodiments, a 50% crossing at code 50 implies zero offset between the single ended signals. In the illustrated implementation, the crossing control range is more than +/- 20%.

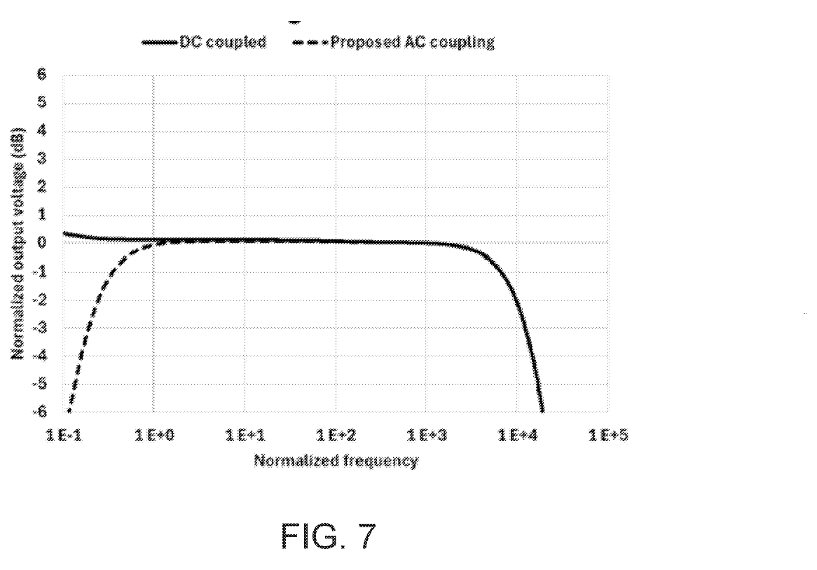

FIG. 7 illustrates the frequency response of a circuit design incorporating a biasing and crossing control circuit 212 in accordance with embodiments of the present disclosure and a circuit design not incorporating a biasing and crossing control circuit 212. Specifically, FIG. 7 compares the frequency response of the two designs (e.g., with and without the biasing and crossing control circuit 212 as well as DC blocking capacitors C1, C2). The output voltage gain is normalized to its value at the normalized frequency of 1 (1E+0). The solid line illustrates the frequency response when the on-chip DC blocking capacitors C1, C2 are not implemented, consequently, the low frequency gain goes to lower frequencies; however, this design will require off-chip blocking capacitors.

The dashed line illustrates the frequency response when on-chip DC blocking capacitors C1, C2 are used according to embodiments of the present disclosure. In other words, the dashed line illustrates the frequency response when a biasing and crossing control circuit 212 is implemented as part of circuit 200. As can be seen in FIG. 7, the frequency response above the target LFC (e.g., 1E0) remains unchanged, satisfying the target LFC frequency response.

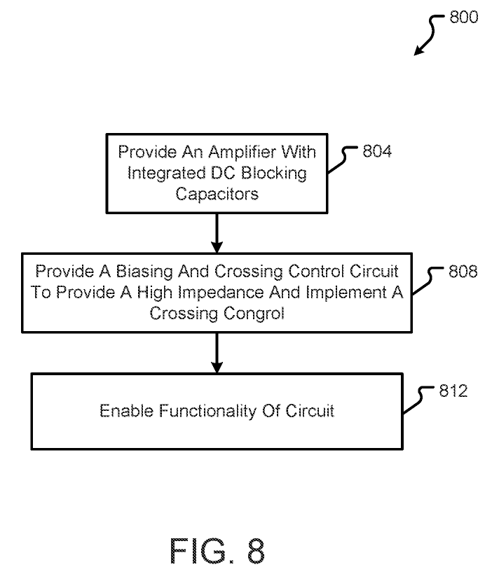

Referring now to FIG. 8, a method 800 will be described in accordance with at least some embodiments of the present disclosure. The method 800 begins by providing an amplifier 204 with integrated DC blocking capacitors (e.g., capacitors C1, C2) (step 804).

The method 800 further includes providing a biasing and crossing control circuit 212 to correct biasing of the amplifier 204 and to provide crossing control for the amplifier 204 (step 808). The functionality of the biasing and crossing control circuit 212 may, in some embodiments, be enabled or disabled, depending upon whether functionality of the biasing and crossing control circuit 212 is desired for an application in which the amplifier 204 is deployed (step 812). For instance, the biasing and crossing control circuit 212 may be provided as part of circuit 200, but the functionality thereof may not need to be implemented, meaning that the offset control provided by the biasing and crossing control circuit 212 may be substantially zero or near zero.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A circuit, comprising:
a first blocking capacitor coupled to an input of an amplifier;
a second blocking capacitor coupled to the input of the amplifier;
one or more transistors that operate as amplifier components for the amplifier; and
a biasing and crossing control circuit to provide bias control and offset compensation for the amplifier, wherein the biasing and crossing control circuit further provides a crossing control for the amplifier.

2. The circuit of claim 1, wherein the one or more transistors comprise a first transistor and a second transistor.

3. The circuit of claim 2, wherein the biasing and crossing control circuit senses a first voltage at an input of the first transistor and a second voltage at an input of the second transistor and uses the first voltage and the second voltage to control an amount of offset for the offset compensation.

4. The circuit of claim 3, wherein the amount of offset is set by a crossing control Digital-to-Analog Converter (DAC).

5. The circuit of claim 4, further comprising a fully differential operational amplifier that receives an output from the biasing and crossing control circuit and that provides feedback to the input of the amplifier.

6. The circuit of claim 5, wherein the fully differential operational amplifier receives an additional input from a second DAC and wherein the additional input comprises a common-mode voltage reference.

7. The circuit of claim 6, wherein the fully differential operational amplifier extracts a common-mode voltage from the output of the biasing and crossing control circuit and matches the common-mode voltage to the common-mode voltage reference.

8. The circuit of claim 7, wherein the fully differential operational amplifier matches the common-mode voltage to the common-mode voltage reference by setting an input voltage at the one or more transistors equal to an offset provided by the crossing control DAC.

9. The circuit of claim 8, further comprising one or more resistors connected between an output of the fully differential operational amplifier and an input of the one or more transistors.

10. The circuit of claim 1, wherein the one or more transistors comprise a first transistor and a second transistor, wherein a base of the first transistor is connected directly to the first blocking capacitor, and wherein a base of the second transistor is connected directly to the second blocking capacitor.

11. A semiconductor device, comprising:
an amplifier comprising;
a first blocking capacitor;
a second blocking capacitor;
one or more transistors that operate as amplifier components for the amplifier; and
a biasing and crossing control circuit to provide bias control and offset compensation for the amplifier, wherein the biasing and crossing control circuit further provides a crossing control for the amplifier.

12. The semiconductor device of claim 11, wherein the one or more transistors comprise a first transistor and a second transistor.

13. The semiconductor device of claim 12, wherein the biasing and crossing control circuit senses a first voltage at an input of the first transistor and a second voltage at an input of the second transistor and uses the first voltage and the second voltage to control an amount of offset for the offset compensation.

14. The semiconductor device of claim 13, wherein the amount of offset is set by a crossing control Digital-to-Analog Converter (DAC).

15. The semiconductor device of claim 14, further comprising a fully differential operational amplifier that receives an output from the biasing and crossing control circuit and that provides feedback to the input of the amplifier.

16. The semiconductor device of claim 15, wherein the fully differential operational amplifier receives an additional input from a second DAC and wherein the additional input comprises a common-mode voltage reference.

17. The semiconductor device of claim 16, wherein the fully differential operational amplifier extracts a common-mode voltage from the output of the biasing and crossing control circuit and matches the common-mode voltage to the common-mode voltage reference and wherein the fully differential operational amplifier matches the common-mode voltage to the common-mode voltage reference by setting an input voltage at the one or more transistors equal to an offset provided by the crossing control DAC.

18. A system, comprising:
a first blocking capacitor;
a second blocking capacitor;
a first transistor that operates as a first amplifying component for the amplifier;
a second transistor that operates as a second amplifying component for the amplifier; and
a biasing and crossing control circuit to provide bias control and offset compensation for the amplifier, wherein the biasing and crossing control circuit further provides a breakdown protection for the first transistor and the second transistor, and wherein the biasing and crossing control circuit further provides a crossing control for the amplifier.

19. The system of claim 18, wherein the biasing and crossing control circuit senses a first voltage at an input of the first transistor and a second voltage at an input of the second transistor and uses the first voltage and the second voltage to control an amount of offset for the offset compensation.

20. The system of claim 19, further comprising a fully differential operational amplifier that receives an output from the biasing and crossing control circuit and that provides feedback to the input of the amplifier.
